(19) United States
(12) Patent Application Publication
(10) Pub. No.: US 2025/0088149 A1
(43) Pub. Date: Mar. 13, 2025

(54) Radio-frequency Amplifier with Reliability Protection

(71) Applicant: Apple Inc., Cupertino, CA (US)

(72) Inventor: Ming-Da Tsai, San Jose, CA (US)

(21) Appl. No.: 18/677,449

(22) Filed: May 29, 2024

Related U.S. Application Data
(60) Provisional application No. 63/582,372, filed on Sep. 13, 2023.

(51) Int. Cl. H03F 1/30; H03F 1/02; H03F 3/193

(52) U.S. Cl. CPC H03F 1/305; H03F 1/0222; H03F 3/193; H03F 2200/451; H03F 2200/471; H03F 2200/78

(57) ABSTRACT

Wireless circuitry is provided that includes a radio-frequency amplifier, one or more power supply switches coupled to a power supply terminal of the radio-frequency amplifier, a voltage sensor or power detector coupled to the radio-frequency amplifier and configured to generate a sensor output signal, and a control logic configured to generate a digital control signal for selectively activating and deactivating the power supply switches based on the sensor output signal. A filter or adjustable latency/delay circuit can be coupled between the voltage sensor and the control logic. The filter or adjustable latency/delay circuit can have a bandwidth or latency/delay that is tuned by the control logic.

This application claims the benefit of U.S. Provisional Patent Application No. 63/582,372, filed Sep. 13, 2023, which is hereby incorporated by reference herein in its entirety.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver.

Radio-frequency amplifiers can be subject to large voltage swings. If care is not taken, the large voltage swings can negatively impact the reliability and contribute to aging of the radio-frequency amplifiers.

### SUMMARY

An electronic device may include wireless communications circuitry. The wireless communications circuitry may include one or more processors or signal processing blocks for generating baseband signals, a transceiver for upconverting (modulating) the baseband signals to radio frequencies and for downconverting (demodulating) radio-frequency signals to baseband signals, a radio-frequency power amplifier for amplifying radio-frequency signals prior to transmission at one or more antennas, and a radio-frequency low noise amplifier for amplifying radio-frequency signals received at one or more antennas in the electronic device. Power (transmitting) amplifiers and low noise (receiving) amplifiers can be referred to collectively as radio-frequency amplifiers.

An aspect of the disclosure provides wireless circuitry that includes a radio-frequency amplifier, a plurality of power supply switches coupled to a power supply terminal of the radio-frequency amplifier, a voltage sensor coupled to the radio-frequency amplifier and configured to output a sensor output signal, and a control logic configured to generate a digital control signal for selectively activating and deactivating the plurality of power supply switches based on the sensor output signal. The power supply switches can include a first power supply switch having a first terminal coupled to the power supply terminal of the radio-frequency amplifier and having a second terminal coupled to a power supply line on which a positive power supply voltage is provided, a resistor, and a second power supply switch coupled in series with the resistor between the power supply terminal of the radio-frequency amplifier and the power supply line. The wireless circuitry can further include a filter having an input coupled to the voltage sensor and having an output coupled to the control logic. The control logic can output a filter adjustment signal for adjusting the filter between a first mode with a first bandwidth and a second mode with a second bandwidth different than the first bandwidth.

The control logic can include a comparator circuit having a first voltage threshold and a second voltage threshold different than the first voltage threshold. The comparator circuit can include a first comparator having p-type input transistors, a second comparator having n-type input transistors, a first inverting buffer having an input coupled to the first comparator via a first switch and coupled to the second comparator via a second switch, wherein the first switch is also coupled to an output of the first inverting buffer, a second inverting buffer having an input coupled to the first inverting buffer and having an output coupled to the second switch, and a resistive array coupled to the output of the second inverting buffer, to an input of the first comparator, and to an input of the second comparator, where the resistive array is configured to receive a reference voltage. The first comparator can be selectively activated and deactivated based on a first control signal generated at the output of the first inverting buffer, whereas the second comparator can be selectively activated and deactivated based on a second control signal generated at the output of the second inverting buffer.

An aspect of the disclosure provides circuitry that includes a radio-frequency amplifier, a voltage sensor coupled to the radio-frequency amplifier and configured to generate a sensor output signal, a filter configured to filter the sensor output signal and to generate a corresponding filtered signal, and a control logic configured to adjust one or more components associated with the radio-frequency amplifier based on the filtered signal. The one or more components can include power supply switches. The control logic can be further configured to output a bandwidth adjustment signal for selectively configuring the filter in a first mode with a first bandwidth and a second mode with a second bandwidth different than the first bandwidth.

An aspect of the disclosure provides circuitry that includes an amplifier, a sensor configured to monitor a signal associated with the amplifier and to generate a corresponding sensor output signal, a control circuit configured to control one or more components associated with the amplifier based on the sensor output signal, and an adjustable latency circuit coupled between the sensor and the control circuit. The adjustable latency circuit can have an adjustable latency that is tuned by the control circuit.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram showing of an illustrative radio-frequency amplifier having an output coupled to associated power supply control circuitry in accordance with some embodiments.

FIG. 4A is a diagram showing of an illustrative radio-frequency amplifier having an internal node coupled to associated power supply control circuitry in accordance with some embodiments.

FIG. 4B is a diagram showing of an illustrative radio-frequency amplifier having an input coupled to associated power supply control circuitry in accordance with some embodiments.

FIG. 5 is a timing diagram showing how a protection scheme that is triggered by an instantaneous modulation peak voltage swing can lead to an excessive amount of power supply switching.

FIG. 6 is a timing diagram showing how a protection scheme that monitors a filtered voltage swing can avoid excessive power supply switching in accordance with some embodiments.

FIG. 7 is a diagram showing illustrative amplifier supply control circuitry having a voltage sensor, a filter, and control logic in accordance with some embodiments.

FIG. 8 is a diagram showing an adjustable filter response in accordance with some embodiments.

FIG. 9 is a circuit diagram of an illustrative tunable filter in accordance with some embodiments.

FIG. 10 is circuit diagram of an illustrative comparator circuit with complementary p-type and n-type comparators with a feedback path in accordance with some embodiments.

FIG. 11 is a plot of output voltage as a function of input voltage showing hysteresis of the comparator circuit of the type shown in FIG. 10 in accordance with some embodiments.

### DETAILED DESCRIPTION

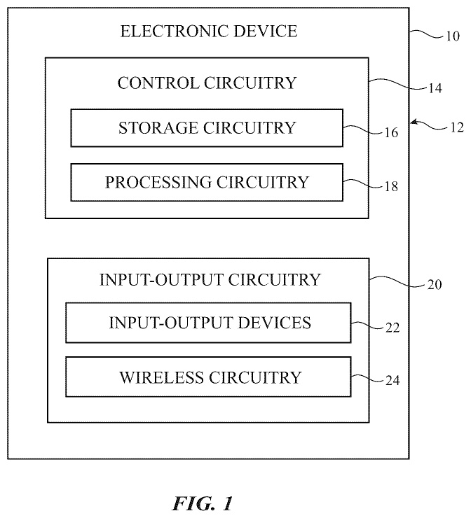

An electronic device such as electronic device 10 of FIG. 1 may be provided with wireless circuitry. Wireless circuitry can include radio-frequency (RF) amplifiers such as power amplifiers and low noise amplifiers. Power amplifiers (“PAs”) can be used to amplify radio-frequency signals in a transmit path and are sometimes referred to as RF transmitting amplifiers, whereas low noise amplifiers (“LNAs”) can be used to amplify radio-frequency signals in a receive path and are sometimes referred to as RF receiving amplifiers. Power amplifiers and low noise amplifiers can sometimes be referred to collectively as radio-frequency amplifiers.

To provide radio-frequency amplifiers with sufficient linearity, the amplifiers can be operated using a relatively high power supply voltage. For radio-frequency amplifiers that include one or more inductors, a high power supply voltage can result in an inductive peaking that leads to very large voltage swings at the outputs of such amplifiers when the inputs are being overdriven. In accordance with some embodiments, a radio-frequency amplifier can be provided with associated power supply control circuitry configured to dynamically reduce the power supply voltage of the amplifier when the amplifier is overdriven. The power supply control circuitry can include a voltage sensor, a filter or bandwidth/latency/delay control circuit, a Schmitt trigger, and other control logic coupled to a power supply terminal of the amplifier in a digital control loop. Controlling a radio-frequency amplifier in this way can be technically advantageous and beneficial to provide fast control loop for addressing the reliability and aging issues that arise when large voltage swings are detected.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz or tremendously high frequency bands), other centimeter or millimeter wave frequency bands between 10-300 GHz, near-field communications frequency bands (e.g., at 13.56 MHZ), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

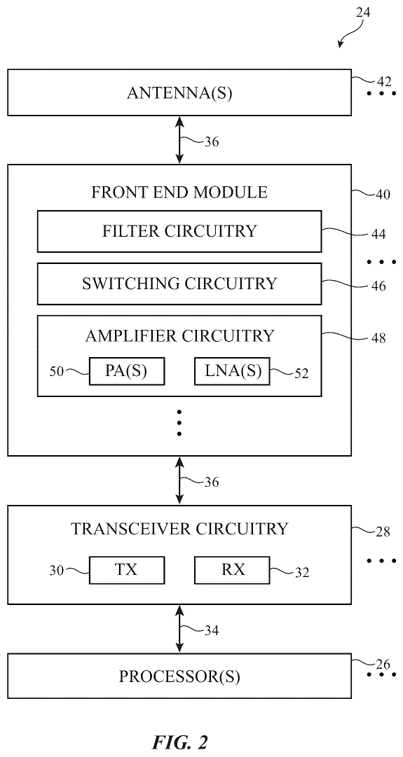

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 configured to generate a current that at least partially cancels a non-linear current associated with the input transistor into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHZ), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, radio transceiver circuitry that handles unlicensed radio bands reserved for industrial, scientific, and medical (ISM) purposes, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

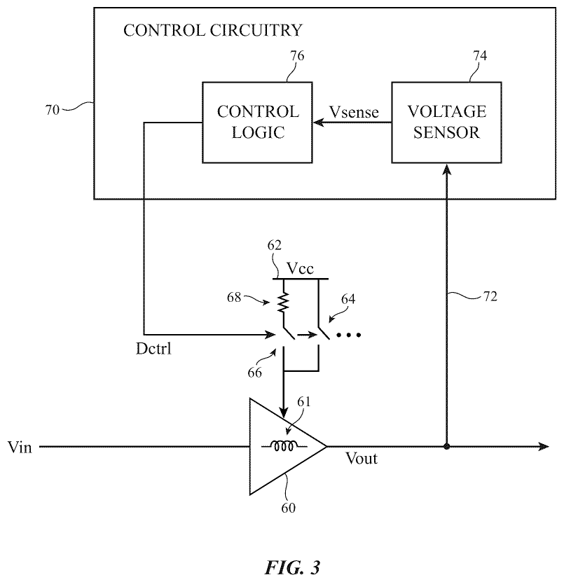

FIG. 3 is a diagram showing of an illustrative radio-frequency amplifier 60 having an output port coupled to associated power supply control circuitry such as power supply control circuitry 70. Radio-frequency (RF) amplifier 60 may represent a radio-frequency transmitting amplifier (e.g., power amplifier 50 of FIG. 2) or may represent a radio-frequency receiving amplifier (e.g., low noise amplifier 52 of FIG. 2). Radio-frequency amplifier 60 may optionally include one or more inductor(s) 61. Radio-frequency amplifier 60 can include transistors, which can be linear or non-linear devices depending on their mode or region of operation. To help ensure that the transistors within amplifier 60 operating linearly, amplifier 60 can be provided with a relatively high positive power supply voltage Vcc. As examples, RF amplifier power supply voltage Vcc can be greater than 5 V, 5-10 V, 10-15V, 15-20 V, 20-30 V, 30-40 V, or other high voltage level.

In the example of FIG. 3, radio-frequency amplifier 60 can have an input port configured to receive a radio-frequency input signal (see input voltage Vin), an output port on which a corresponding amplified voltage signal Vout is generated and a power supply terminal configured to selectively receive positive power supply voltage Vcc (e.g., positive power supply voltage Vcc that is provided on a power supply line 62). Radio-frequency amplifier 60 can be operated using different digital modulation schemes to transmit digital data over radio-frequency channels such as quadrature phase shift keying (QPSK) and quadrature amplitude modulation (QAM). QPSK is a type of phase modulation where four different phase states are used to represent different combinations of a two-bit symbol. The four phase states are separated by 90 degrees (e.g., 0°, 90°, 180°,) 270°. On the other hand, QAM is a modulation scheme that combines both amplitude and phase modulation to encode digital data. Relative to QPSK, QAM allows for a higher number of symbols to be transmitted in each modulation interval, which can enable a higher data transmission rate. The number of symbols in QAM can be represented as “N-QAM,” where N is equal to the number of possible symbols. For example, 16-QAM has 16 constellation points (e.g., 4 amplitude levels and 4 phase states), 64-QAM has 64 constellation points, 256-QAM has 256 constellation points, and so on. Although the examples herein sometimes refer to QPSK and QAM, the embodiments described herein can optionally be extended to other types of wireless modulation schemes, including but not limited to binary phase shift keying (BPSK), minimum shift keying (MSK), orthogonal frequency division multiplexing (OFDM), continuous phase modulation (CPM), and/or other digital signal modulation schemes.

In practice, input signal Vin that is modulated in accordance with QPSK, 64-QAM, or other types of modulation schemes can sometimes result in a large (overshoot) voltage Vout at the output of amplifier 60. A Vout with overly large signal amplitude can be a result of inductive peaking caused by one or more inductors 60 within amplifier 60. Such inductive peaking can sometimes result in a 2*Vcc voltage swing at the output of amplifier 60, which can lead to reliability or aging issues at amplifier 60. It is within this context that the embodiments herein arise.

In the example of FIG. 3, amplifier 60 can receive positive power supply voltage Vcc via switch 64 when signals at amplifier 60 are within a set of limits and can alternatively receive a reduced power supply voltage via switch 66 when signals at amplifier 60 exceed the set of limits. In other words, when reasonable or otherwise low(er) voltage swings are detected at amplifier 60, switch 64 can be activated (turned on) to connect the power supply terminal of amplifier 60 directly to the Vdd power supply line 62. On the other hand, when high(er) voltage swings (e.g., when signal amplitudes exceed a certain threshold) are detected at amplifier 60, switch 66 can be activated to connect the power supply terminal of amplifier 60 indirectly to power supply line 62 via a resistor 68. The scenario where higher voltage swings are present or detected at amplifier 60 is sometimes referred to as an “overvoltage” event. Resistor 68 can be configured to provide a voltage drop such that a reduced power supply voltage that is some delta voltage less than Vcc is presented to the power supply terminal of amplifier 60. As examples, resistor 68 (when switched into use) can provide a voltage drop of at least 10 mV, 10-50 mV, 50-100 mV, 100-200 mV, 200-500 mV, 0.5-1 V, 1-2 V, 2-3 V, or other amount of voltage drop.

The term “activate” with respect to a switch (or transistor) may refer to or be defined herein as an action that places the switch in an on or low-impedance state such that the two terminals of the switch are electrically connected to conduct current. The term “deactivate” with respect to a switch (or transistor) may refer to or be defined herein as an action that places the switch in an off or high-impedance state such that the two terminals of the switch/transistor are electrically disconnected with minimal leakage current.

Switches 64 and 66 that are coupled to the power supply terminal of amplifier 60 are sometimes referred to as amplifier power supply switches. The example of FIG. 3 in which amplifier 60 is coupled to two power supply switches 64 and 66 is illustrative. If desired, amplifier 60 may be coupled to three or more power supply switches each of which is configured to provide a different amount of power supply voltage down to the power supply terminal of amplifier 60.

Power supply switches 64 and 66 can be controlled by associated control circuitry 70. Control circuitry 70 that is configured to selectively activate and deactivate power supply switches 64 and 66 is sometimes referred to as amplifier power supply control circuitry. As shown in FIG. 3, amplifier power supply control circuitry 70 can include a voltage sensor circuit such as voltage sensor 74 and a separate control circuit such as control logic 76. Voltage sensor 74 may have an input configured to receive output voltage Vout from the output port of amplifier 60 via sensing path 72 and may have an output on which a corresponding sensor output signal/voltage Vsense is generated. Control logic 76 (or control circuit) may receive the sensor output voltage Vsense, analyze Vsense, and based on the analysis of Vsense, output a corresponding digital control signal Dctrl for selectively activating and deactivating switches 64 and 66. Only one of switches 64 and 66 should be activated at any point in time during the operation of amplifier 60. Adjusting the amplifier power supply voltage using an open-loop digital control loop in this way can be technically beneficial and advantageous over closed-loop analog control loops that typically exhibit bandwidth and stability concerns and slower response times. Amplifier power supply control circuitry 70 that is used to dynamically reduce the power supply voltage for RF amplifier 60 during overvoltage scenarios can sometimes be referred to as overvoltage protection circuitry.

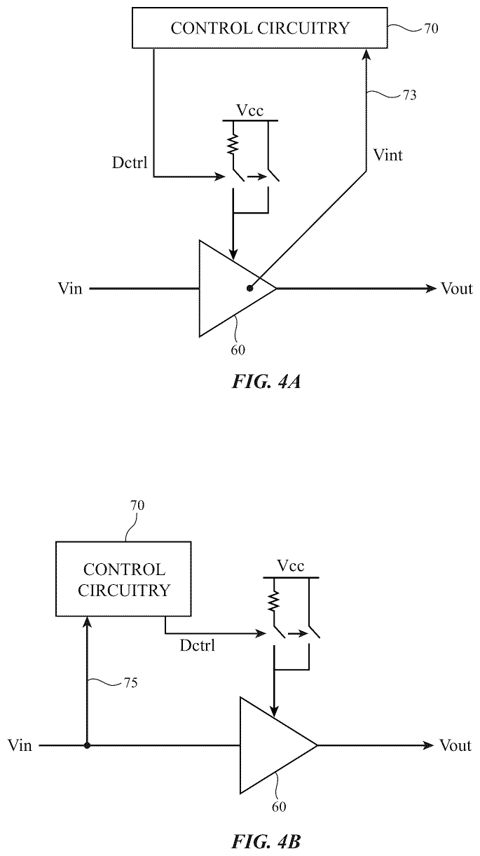

The embodiment of FIG. 3 in which voltage sensor 74 is configured to monitor the output voltage Vout of radio-frequency amplifier 60 is exemplary. FIG. 4A shows another embodiment in which control circuitry 70 is configured to monitor one or more internal voltage Vint within amplifier 60 via sensing path 73. For example, the voltage sensor within amplifier power supply control circuitry 70 can monitor (via sensing path 73) the voltage level of any internal node, a bias voltage, a differential voltage, and/or a common mode voltage associated with amplifier 60. FIG. 4B shows yet another embodiment in which control circuitry 70 is configured to monitor the input voltage Vin at the input port of amplifier 60 via sensing path 75. In this example, the voltage sensor within amplifier power supply control circuitry 70 can monitor (via sensing path 75) the voltage level of input radio-frequency signal Vin that is being received at the input port of amplifier 60. The examples of FIGS. 3, 4A, and 4B are illustrative. In general, amplifier power supply control circuitry 70 can be configured to adjust or tune the power supply switches based on one or more voltages at the input port, output port, or some internal node within amplifier 60, and/or based on other voltage associated with the operation of amplifier 60. In other embodiments, voltage sensor 74 can alternatively be implemented as a power detector, current sensor, or other sensing circuit for monitoring an input, output, or internal signal level associated with amplifier 60.

FIG. 5 is a timing diagram showing how an overvoltage protection scheme that is triggered based on an instantaneous modulation peak voltage swing can lead to an excessive amount of power supply switching. Waveform 80 may represent the modulated waveform at the output of amplifier 60 and is therefore sometimes referred to as a modulated amplifier output waveform. Waveform 82 may represent the waveform at the output of voltage sensor 74 and is therefore sometimes referred to as a voltage sensor output waveform (see, e.g., signal Vsense in FIG. 3). Waveform 84 may represent the digital control signal at the output of control logic 76 and is therefore sometimes referred to as a control logic output signal or digital control signal.

At time t0, the digital control signal 84 is high, which may correspond to a first mode of operation, phase, or state during which the nominal positive power supply voltage Vcc is provided to the power supply terminal of amplifier 60. In this example, a high digital control signal 84 may result in activating power supply switch 64 and deactivating power supply switch 66. In general, digital control signal 84 can be a one-bit digital signal or a multi-bit digital signal.

At time t1, the modulated amplifier output waveform 80 may have a peak, which results in the voltage sensor output waveform 82 exceeding a certain threshold (sometimes referred to as a high voltage threshold). This can cause control logic 76 to deassert digital control signal 84 (e.g., to drive signal 84 low). A low digital control signal 84 may correspond to a second mode of operation, phase, or state during which a reduced power supply voltage is provided to the power supply terminal of amplifier 60 via resistor 68. In this example, a low digital control signal 84 may result in deactivating power supply switch 64 and activating power supply switch 66. As shown in the time period from t1 to t2, operating amplifier 60 in a low power supply voltage mode can help shift the modulated amplifier output waveform 80 to a lower level within a relatively short period of time, which also causes the sensor output waveform 82 to fall quickly.

At time t2, the modulated amplifier output waveform 80 may fall even further, which results in the voltage sensor output waveform 82 to fall below a low voltage threshold. This can cause control logic 76 to reassert digital control signal 84 (e.g., to drive signal 84 back high). As describe above, a high digital control signal 84 may correspond to the first mode of operation during which the nominal power supply voltage Vcc is provided to the power supply terminal of amplifier 60 via activated power supply switch 64. As shown in the time period from t2 to t3, operating amplifier 60 in the high/nominal power supply voltage mode can help shift the modulated amplifier output waveform 80 back up to the higher level within a relatively short period of time.

At time t3, the modulated amplifier output waveform 80 may exhibit another peak, which might cause digital control signal 84 to be deasserted again. Driving digital control signal 84 low will activate power supply switch 66 while deactivating power supply switch 64 so that amplifier 60 receives the reduced power supply voltage via resistor 68. At time t4, the modulated amplifier output waveform 80 may again fall below the low voltage threshold, which would cause digital control signal 84 to be reasserted back high. Driving digital control signal 84 high will deactivate power supply switch 66 while activating power supply switch 64 so that amplifier 60 receives the nominal/high power supply voltage Vcc. As shown in the example of FIG. 5, controlling digital control signal 84 based on the instantaneous modulation peak voltage swing of waveform 80 might cause the digital control signal 84 to switch quite often, even when the power of a blocker signal at the amplifier input port is unchanged. Such behavior of over frequent switching between the first (high/nominal power supply voltage) mode and the second (reduced power supply voltage) mode can lead to undesired system oscillation.

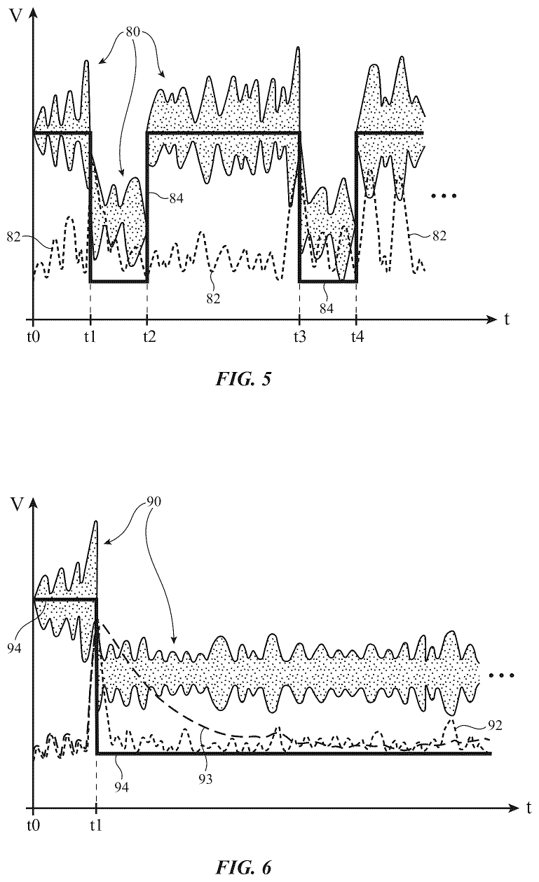

In accordance with some embodiments, the toggling of the digital control signal can be performed based on a filtered version of the voltage sensor output waveform instead of the instantaneous modulation peak voltage swing of the modulated amplifier output waveform. FIG. 6 is a timing diagram showing how an illustrative overvoltage protection scheme that is triggered based on a filtered version of the sensor output waveform in accordance with some embodiments can help prevent excessive amplifier power supply switching. Waveform 90 may represent the modulated waveform at the output of amplifier 60 and is therefore sometimes referred to as a modulated amplifier output waveform. Waveform 92 may represent the waveform at the output of voltage sensor 74 and is therefore sometimes referred to as a voltage sensor output waveform (see, e.g., sensor output signal Vsense in FIG. 3). Waveform 93 may represent a filtered version of the voltage sensor output waveform 92 and is therefore sometimes referred to as a filtered voltage sensor output waveform. Waveform 94 may represent the digital control signal at the output of control logic 76 and is therefore sometimes referred to as a control logic output signal or digital control signal.

At time t0, the digital control signal 94 is high, which may correspond to the first mode of operation, phase, or state during which the nominal positive power supply voltage Vcc is provided to the power supply terminal of amplifier 60. In this example, a high digital control signal 94 may result in activating power supply switch 64 and deactivating power supply switch 66. In general, digital control signal 94 can be a one-bit digital signal or a multi-bit digital signal.

At time t1, the modulated amplifier output waveform 90 may have a peak, which results in the voltage sensor output waveform 92 exceeding a certain threshold (sometimes referred to as a high voltage threshold). This can cause control logic 76 to deassert digital control signal 94 (e.g., to drive signal 94 low). A low digital control signal 94 may correspond to the second mode of operation, phase, or state during which a reduced power supply voltage is provided to the power supply terminal of amplifier 60 via resistor 68. In this example, a low digital control signal 94 may result in deactivating power supply switch 64 and activating power supply switch 66. At this point (e.g., at time t1), the voltage sensor output waveform 92 can be filtered using a narrowband filter to produce a filtered waveform 93 having a much slower settling time. This slower settling time introduced by filter 100 should always be from high voltage to low voltage. As shown in the example of FIG. 6, controlling digital control signal 94 based on the filtered voltage sensor output waveform 93 can be technically advantageous and beneficial by avoiding overly frequent power supply switching and system oscillation.

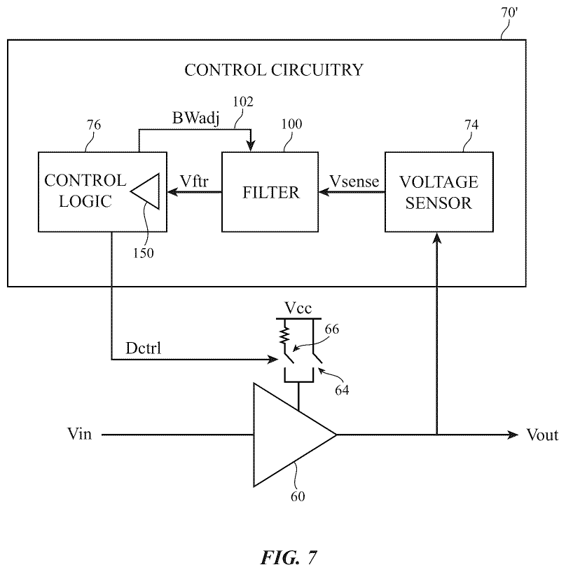

Such filtering can be achieved using a filtering circuit such as filter 100 that is coupled between voltage sensor 74 and control logic 76 (see, e.g., the embodiment of FIG. 7). As shown in FIG. 7, filter 100 may have an input configured to receive the voltage sensor output (waveform) Vsense from voltage sensor 74 and an output on which a filtered signal Vftr is generated and conveyed to control logic 76. Control logic 76 can generate a digital control signal Dctrl (e.g., a one-bit digital signal or a multi-bit digital signal) for controlling the power supply switches 64 and 66 and a filter adjustment (tuning) signal BWadj for tuning a bandwidth of filter 100. Control logic 76 can toggle signal BWadj to toggle filter 100 between at least two different modes of operation. Filter 100 can be implemented as an analog filter, a digital filter, or any circuit that can introduce different bandwidth, latency, or delay.

For example, during the first (high voltage Vcc) mode when switch 64 is activated, control logic 76 may output signal BWadj that configures filter 100 in a wide bandwidth mode so that filter 100 operates as a wideband filter. During the second (reduced voltage) mode when switch 66 is activated, control logic 76 may output signal BWadj that configures filter 100 in a narrow bandwidth mode so that filter 100 operates as a narrowband filter. The wide bandwidth mode may correspond to a short latency/delay mode in the time domain such that the temporal response of filter 100 is fast to capture the instantaneous peak voltage waveform with low latency (as shown in the temporal response of waveform 93 prior to time t1). In contrast, the narrow bandwidth mode may correspond to a long latency/delay mode in the time domain such that the temporal response of filter 100 averages out the voltage sensor waveform with longer latency (as shown in the temporal response of waveform 93 after time t1). Selectively configuring filter 100 in different filtering modes (e.g., between a wide bandwidth mode during the high/nominal power supply voltage mode and a narrow bandwidth mode during the reduced/low power supply voltage mode) can be technically advantageous and beneficial to avoid overly frequent power supply switching and system oscillation.

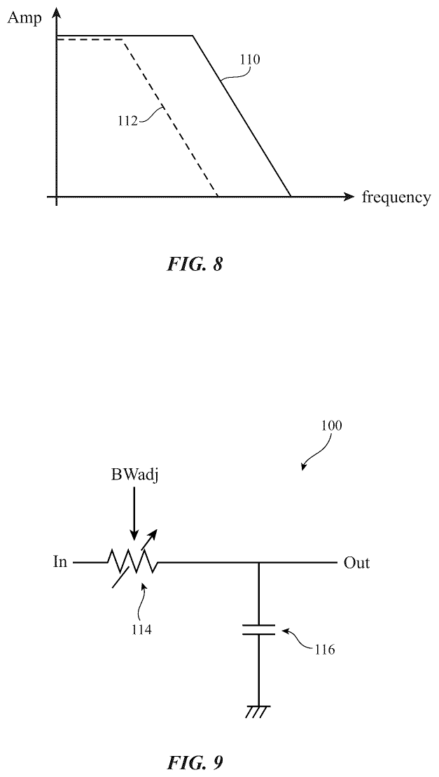

FIG. 8 is a diagram showing an adjustable filter response of filter 100 (e.g., plotting the amplitude of the output signal as a function of frequency). As shown in FIG. 8, line 110 represents the frequency response of filter 100 when filter 100 is configured in the wide bandwidth mode before the overvoltage protection mechanism is activated (e.g., when amplifier 60 is configured to receive the full nominal Vcc). Line 112 represents the frequency response of filter 100 when filter 100 is configured in the narrow bandwidth mode after the overvoltage protection mechanism is activated (e.g., when amplifier 60 is configured to receive the reduced Vcc). In the time domain, a wideband filter provides shorter latency or delay, whereas a narrowband filter provides longer latency or delay. Filter 100 can thus sometimes also be referred to as an adjustable delay circuit or an adjustable latency circuit that is operable between a low latency/delay mode and a high latency/delay mode.

FIG. 9 is a circuit diagram showing one exemplary implementation of filter 100. As shown in FIG. 9, filter 100 may include a resistive component such as resistor 114 and a capacitive component such as capacitor 116. Resistor 114 may be an adjustable resistor. Adjustable resistor 114 may have a first terminal coupled to a filter input port In and a second terminal coupled to a filter output port Out. Capacitor 116 may have a first terminal coupled to the filter output port Out and a second terminal coupled to a ground line. Adjustable resistor 114 may have a variable resistance that is tuned based on filter control signal BWadj output from control logic 76. For example, control logic 76 may output signal BWadj that decreases the value of adjustable resistor 114 to configure filter 100 in the wideband mode and may output signal BWadj that increases the value of adjustable resistor 114 to configure filter 100 in the narrowband mode. If desired, the shunt capacitor 116 can also have an adjustable capacitance tuned using signal BWadj for adjusting the bandwidth of filter 100. The example of FIG. 9 shows filter 100 implemented as an analog filter. In general, other ways of implementing an adjustable or tunable filter 100 can be employed. Filter 100 can, as examples, be implemented as an analog filter, a digital filter, or any circuit that can introduce adjustable bandwidth, latency, or delay.

The example of FIG. 7 in which control logic 76 is configured to output a digital control signal Dctrl for controlling the power supply switches 64 and 66 of amplifier 60 is illustrative. If desired, control logic 76 can additional or alternatively be configured to output one or more digital control signals and/or one or more analog control signals for adjusting or tuning any internal circuit components within amplifier 60 to provide overvoltage protection. For example, control logic 76 can output analog/digital control signal(s) for adjusting one or more bias voltage within amplifier 60, for selectively activating/deactivating one or more portions of amplifier 60, for selectively configuring amplifier 60 in different operating modes, etc.

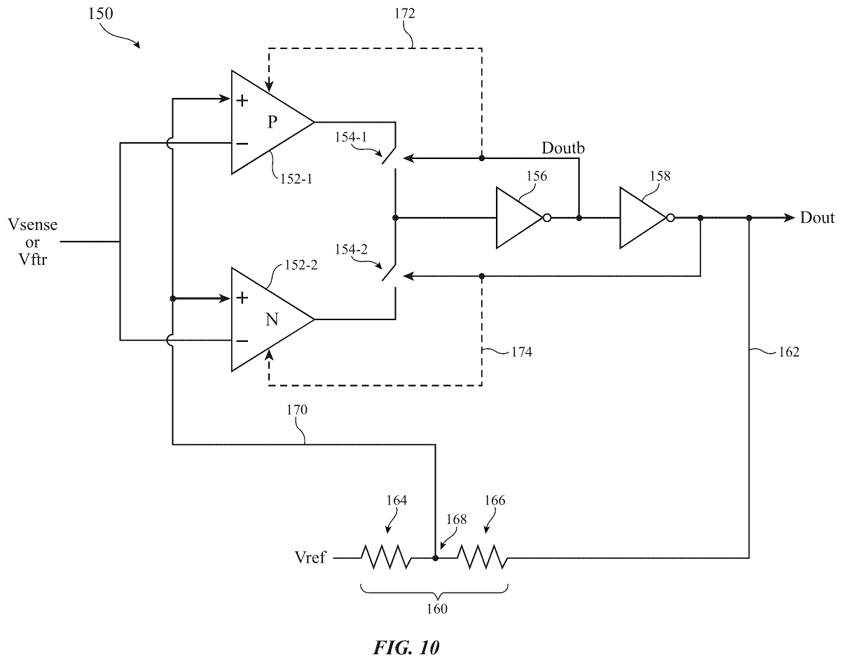

To help further avoid unexpected mode switching, control logic 76 can include a comparator circuit such as comparator 150 having separate high and low trigger thresholds. Comparator 150 with different trigger thresholds is sometimes referred to as a Schmitt trigger circuit. FIG. 10 is circuit diagram of an illustrative comparator circuit 150 with complementary p-type and n-type comparators with a feedback path. As shown in FIG. 10, comparator circuit 150 may include a first comparator such as a p-type comparator 152-1, a second comparator circuit such as an n-type comparator 152-2, switches 154-1 and 154-2, output buffers 156 and 158, and resistive components such as resistor 164 and 166. P-type comparator 152-1 may refer to and be defined herein as a comparator having p-type input transistors (e.g., p-type metal-oxide-semiconductor or PMOS devices) that are more suitable for sensing signals with lower voltages. On the other hand, n-type comparator 152-2 may refer to and be defined herein as a comparator having n-type input transistors (e.g., n-type metal-oxide-semiconductor or NMOS devices) that are more suitable for sensing signals with higher voltages. Comparator circuit 150 that includes both p-type and n-type comparators is sometimes referred to as a complementary comparator circuit.

P-type comparator 152-1 may have a first (negative) input port configured to receive voltage sensor output Vsense or filtered output Vftr, a second (positive) input port, and an output port coupled to an input of buffer 156 via switch 154-1. N-type comparator 152-2 may have a first (negative) input port configured to receive voltage sensor output Vsense or filtered output Vftr, a second (positive) input port, and an output port coupled to the input of buffer 156 via switch 154-2. Buffers 156 and 158 can be inverting buffers or drivers (e.g., buffer circuits configured to output an inverted version of a received signal). Inverting buffer 156 may have an output that is coupled to an input of inverting buffer 158. Inverting buffer 158 may have an output on which a digital output signal Dout is generated.

The signal Dout at the output of buffer 158 can be used to selectively activate and deactivate switch 154-2 (e.g., a high Dout can activate switch 154-2, whereas a low Dout will deactivate switch 154-2). The signal Doutb, which is an inverted version of Dout, at the output of buffer 156 can be used to selectively activate and deactivate switch 154-1 (e.g., a high Doutb can activate switch 154-1, whereas a low Doutb will deactivate switch 154-1). If desired, Doutb can further be used to selectively activate and deactivate p-type comparator 152-1 via control path 172 (e.g., a high Dout can activate comparator 152-1, whereas a low Dout will deactivate comparator 152-1). Similarly, signal Dout can further be used to selectively activate and deactivate n-type comparator 152-2 via control path 174 (e.g., a high Dout can activate comparator 152-2, whereas a low Dout will deactivate comparator 152-2). Selectively deactivating p-type comparator 152-1 using Doutb and selectively deactivating n-type comparator 152-2 using Dout can help minimize the power consumption of comparator circuit 150.

The output of inverting buffer 158 may be coupled to resistors 164 and 166 via a feedback path 162. Resistor 166 may have a first terminal coupled to the output of inverting buffer 158 and a second terminal coupled to node 168. Resistor 164 may have a first terminal coupled to node 168 and a second terminal configured to receive a reference voltage Vref. Reference voltage Vref may be equal to or different than power supply voltage Vcc. Resistors 164 and 166 may form part of a resistive array 160, which is sometimes also referred to as a chain of resistors or a resistive chain. Node 168 within the resistive chain 160 may be fed back to the second (positive) input ports of comparators 152-1 and 152-2 via path 170.

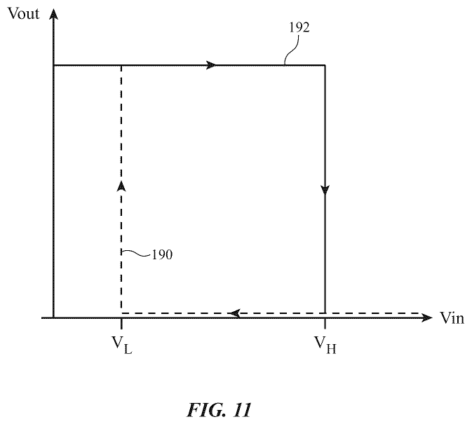

FIG. 11 is a plot of output voltage as a function of input voltage showing hysteresis of complementary comparator circuit 150 of the type shown in FIG. 10. As shown in FIG. 11, line 192 illustrates how Vout can toggle from a high voltage to a low voltage when the input voltage Vin exceeds a first (high) voltage threshold V_{H}. On the other hand, line 190 illustrates how Vout can toggle from a low voltage to a high voltage when the input voltage Vin falls below a second (low) voltage threshold V_{L}. The low voltage threshold V_{L} may be less than the high voltage threshold V_{H}. This characteristic of comparator circuit 150 having different trigger/toggling thresholds depending on the direction of signal transition is sometimes referred to and defined herein as “hysteresis.”

The use of resistive chain 160 within the Schmitt trigger in the example of FIG. 10 can help achieve more precise V_{H} and V_{L} levels, since these voltage levels are a function of the ratio of resistors 164 and 166 (as an example). Furthermore, implementing comparator circuit 150 using complementary p-type and n-type comparators can be technically advantageous and beneficial to help obtain a wider hysteresis range, where the high threshold voltage V_{H} is relatively close to positive power supply voltage Vcc (e.g., V_{H} may be within 10 mV of Vcc, within 20 mV of Vcc, within 20-50 mV of Vcc, within 50-100 mV of Vcc, within 100-200 mV of Vcc, within 1V of Vcc, within 1-2 V of Vcc, within 2-5 V of Vcc, etc.) and where the low threshold voltage V_{L} is relatively close to a ground voltage Vss (e.g., V_{L} may be within 10 mV of Vss, within 20 mV of Vss, within 20-50 mV of Vss, within 50-100 mV of Vss, within 100-200 mV of Vss, within 1V of Vss, within 1-2 V of Vss, within 2-5 V of Vss, etc.).

The methods and operations described above in connection with FIGS. 1-11 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Circuitry comprising:
a radio-frequency amplifier;
a plurality of power supply switches coupled to a power supply terminal of the radio-frequency amplifier;
a voltage sensor coupled to the radio-frequency amplifier and configured to output a sensor output signal; and
a control logic configured to generate a digital control signal for selectively activating and deactivating the plurality of power supply switches based on the sensor output signal.

2. The circuitry of claim 1, wherein the plurality of power supply switches comprises:
a first power supply switch having a first terminal coupled to the power supply terminal of the radio-frequency amplifier and having a second terminal coupled to a power supply line on which a positive power supply voltage is provided.

3. The circuitry of claim 2, wherein the plurality of power supply switches further comprises:
a resistor; and
a second power supply switch coupled in series with the resistor between the power supply terminal of the radio-frequency amplifier and the power supply line.

4. The circuitry of claim 1, further comprising:
a filter having an input coupled to the voltage sensor and having an output coupled to the control logic.

5. The circuitry of claim 4, wherein the control logic is further configured to output a filter adjustment signal for adjusting the filter between a first mode with a first bandwidth and a second mode with a second bandwidth different than the first bandwidth.

6. The circuitry of claim 5, wherein the filter comprises:
an adjustable resistor coupled between an input of the filter and an output of the filter, wherein the adjustable resistor is tuned by the filter adjustment signal; and
a capacitor coupled between the output of the filter and a ground power supply line.

7. The circuitry of claim 1, wherein the control logic comprises:
a comparator circuit having a first voltage threshold and a second voltage threshold different than the first voltage threshold.

8. The circuitry of claim 7, wherein the comparator circuit comprises:
a first comparator having p-type input transistors; and
a second comparator having n-type input transistors.

9. The circuitry of claim 8, wherein the comparator circuit further comprises:
a first inverting buffer having an input coupled to the first comparator via a first switch and coupled to the second comparator via a second switch, wherein the first switch is also coupled to an output of the first inverting buffer.

10. The circuitry of claim 9, wherein the comparator circuit further comprises:
a second inverting buffer having an input coupled to the first inverting buffer and having an output coupled to the second switch.

11. The circuitry of claim 10, wherein the comparator circuit further comprises:
a resistive array coupled to the output of the second inverting buffer, to an input of the first comparator, and to an input of the second comparator, wherein the resistive array is configured to receive a reference voltage.

12. The circuitry of claim 10, wherein the first comparator is selectively activated and deactivated based on a first control signal generated at the output of the first inverting buffer, and wherein the second comparator is selectively activated and deactivated based on a second control signal generated at the output of the second inverting buffer.

13. The circuitry of claim 1, wherein the voltage sensor is coupled to an output port or an input port of the radio-frequency amplifier.

14. The circuitry of claim 1, wherein the voltage sensor is coupled to an internal node within the radio-frequency amplifier.

15. Circuitry comprising:
a radio-frequency amplifier;
a voltage sensor coupled to the radio-frequency amplifier and configured to generate a sensor output signal;
a filter configured to filter the sensor output signal and to produce a corresponding filtered signal; and
a control logic configured to adjust one or more components associated with the radio-frequency amplifier based on the filtered signal.

16. The circuitry of claim 15, wherein the one or more components associated with the radio-frequency amplifier comprises:
a first power supply switch having a first terminal coupled to a power supply terminal of the radio-frequency amplifier and having a second terminal coupled to a power supply line on which a positive power supply voltage is provided; and
a second power supply switch coupled in series with a resistor between the power supply terminal of the radio-frequency amplifier and the power supply line.

17. The circuitry of claim 15, wherein the control logic is further configured to output a bandwidth adjustment signal for selectively configuring the filter in a first mode with a first bandwidth and a second mode with a second bandwidth different than the first bandwidth.

18. The circuitry of claim 15, wherein the control logic further comprises a comparator circuit having a p-type comparator and an n-type comparator.

19. The circuitry of claim 18, wherein the comparator circuit further comprises:
a first inverting buffer;
a first switch coupled between the p-type comparator and the first inverting buffer;
a second switch coupled between the n-type comparator and the first inverting buffer;
a second inverting buffer coupled in series with the first inverting buffer; and
a resistive chain coupled between the second inverting buffer and inputs of the p-type and n-type comparators.

20. Circuitry comprising:
an amplifier;
a sensor configured to monitor a signal associated with the amplifier and to produce a corresponding sensor output signal;
a control circuit configured to control one or more components associated with the amplifier based on the sensor output signal; and
an adjustable latency circuit coupled between the sensor and the control circuit, wherein the adjustable latency circuit has an adjustable latency that is tuned by the control circuit.
